(19) United States
(12) Patent Application Publication
(10) Pub. No.: US 2005/0253171 A1
(43) Pub. Date: Nov. 17, 2005

(54) Organic light emitting display and method of fabricating the same

(76) Inventors: Tae-Wook Kang, Seongnam-si (KR); Seong-Moh Seo, Suwon-si (KR); Chang-Su Seo, Suwon-si (KR); Yu-Sung Cho, Yeongam-gun (KR); Hyun-Eok Shin, Gunpo-si (KR); Kwan-Hee Lee, Seoul (KR)

Correspondence Address: MCGUIREWOODS, LLP, 1750 TYSONS BLVD, SUITE 1800, MCLEAN, VA, 22102, US

(21) Appl. No.: 11/123,012

(22) Filed: May 6, 2005

(30) Foreign Application Priority Data
May 17, 2004 (KR) 2004-34911

(51) Int. Cl. H01L 27/10

(52) U.S. Cl. 257/211

(57) ABSTRACT

An organic light emitting display (OLED) and method of fabricating the same are provided having a reduced number of photolithography and etching steps. The method includes a source electrode and a drain electrode being formed over a substrate, and at least one insulating layer being formed over the source electrode and drain electrode. After the insulation layer is formed, a reflecting layer pattern is formed. A via contact hole is formed through the insulating layer using the reflecting layer pattern as an etching mask. Multiple insulating layers may be formed and have a via contact hole etched therethrough in one etching step using the reflecting layer pattern as a mask. Alternatively, each insulating layer may have a via contact hole separately etched therethrough, with the last layer being etched using the reflective layer pattern as a mask. Consequently, the number of photolithography and etching steps is reduced thereby leading to higher manufacturing yield and lower manufacturing cost.

### CROSS-REFERENCE TO RELATED APPLICATION

This application claims priority to and the benefit of Korean Patent Application No. 2004-34911, filed May 17, 2004, which is hereby incorporated by reference for all purposes as if fully set forth herein.

### BACKGROUND OF THE INVENTION

1. Field of the Invention

The present invention relates to an organic light emitting display and method of fabricating the same and, more particularly, to an organic light emitting display and a method for manufacturing the same in which a planarization layer is etched using a reflecting layer pattern as an etching mask to form a via contact hole, thereby simplifying the manufacturing process.

2. Description of the Related Art

An organic light emitting display (OLED) is an emissive display in which a fluorescent organic compound is electrically excited to emit light. OLEDs may be classified as either a passive matrix type or an active matrix type according to the manner of driving the OLEDs pixels which are arranged in N×M matrix. The active matrix OLED has lower power consumption compared to the passive matrix OLED, making it more suitable for a large-sized display. Active matrix OLEDs also have higher resolution.

OLEDs may also be classified as either a top emission type, a bottom emission type, or a double-sided emission type according to the direction of light emitted from the organic compound. The top emission OLED emits light in a direction opposite to an underlying substrate having the unit pixels formed thereon. The top emission OLED also has a high opening ratio and a large aperture ratio, unlike the bottom emission OLED. It should also be noted that because the OLED is an emissive display, it does not need a separate light source, and may include a reflecting layer made of a high reflectivity metal to reflect external light. The reflected external light may be used as a source of additional light in order to increase luminous efficiency.

FIG. 1A, FIG. 1B and FIG. 1C are cross-sectional views illustrating a method of fabricating a conventional OLED.

Referring to FIG. 1A, a buffer layer 110 having a predetermined thickness is formed on a substrate 100. A polysilicon pattern 122, from which a thin film transistor (TFT) will be formed, is arranged on the buffer layer 110. Next, source and drain regions 120 into which impurity ions are implanted are formed in both sides of the polysilicon pattern 122. A gate insulating layer 130 is then formed over the surface of the buffer layer 110 and the polysilicon pattern 122.

A gate electrode 132 is then formed on the gate insulating layer 130 over the polysilicon pattern 122. After the gate electrode 132 is formed, an interlayer insulating layer 140 may be formed over the gate electrode 132 and gate insulating layer 130. The interlayer insulating layer 140 has via holes formed therein, and a source electrode 150 and a drain electrode 152 are formed in the via holes. A passivation layer 160 having a predetermined thickness is then formed over the source electrode 150, drain electrode and interlayer insulating layer 140. The passivation layer 160 is then etched by well known photolithography and etching processes to form a first via contact hole 162 which exposes the drain electrode 152. Alternatively, the source electrode 150 may be exposed by a contact hole through the passivation layer. The passivation layer 160 may be formed of either a silicon nitride layer or a silicon oxide layer, or a stacked layer arrangement have a silicon nitride layer and a silicon oxide layer. Alternatively, the source electrode 150, drain electrode 152 and the passivation layer 160 may be formed without an underlying insulating layer 140.

Referring to FIG. 1B, a planarization layer 170 is formed over the surface of the passivation layer 160. The planarization layer 170 may be formed from any material selected from a group of materials consisting of polyimide, benzocyclobutene-based resin, spin on glass (SOG), and acrylate. The planarization layer 170 is etched by photolithography and a suitable etching processes to form a second via contact hole 172 which exposes the first via contact hole 162.

Referring to FIG. 1C, a reflecting layer is formed over the planarization layer 170. The reflecting layer is made of a metal having a high reflectivity such as, for example, aluminum (Al), silver (Ag) or an alloy of aluminum and silver. The reflecting layer is then etched by photolithography and a suitable etching process to form a reflecting layer pattern 180 over a portion of the planarization layer 170. The reflecting layer pattern 180 is formed at a position corresponding to a pixel electrode which will be formed in subsequent processes and which does not interfere with the first via contact hole 162 and second via contact hole 172.

A pixel electrode material layer made of a thin layer of a transparent conductive material such as indium thin oxide (ITO) is then formed over the surface of the reflecting layer pattern 180, planarization layer 170, and in contact with the drain electrode 152 through the first via contact hole 162 and second via contact hole 172. Thereafter, the pixel electrode material layer is etched by photolithography to form a pixel electrode 182. Finally, an insulating layer pattern 190 is formed over a portion of the surface of the structure to define a pixel region over the pixel electrode. The insulating layer pattern 190 may be made of a material selected from a group of materials consisting of polyimide, benzocyclobutene, phenol-like resin, and acrylate.

As described above, the conventional method of fabricating an OLED requires numerous time consuming steps such as forming the reflecting layer, the first via contact hole, and the second via contact hole by the respective photolithography and etching processes. As such, the respective photolithography and etching processes for forming the reflecting layer, the first via contact and the second via contact lead to high manufacturing costs, and low manufacturing yields due to a higher error probability.

### SUMMARY OF THE INVENTION

The present invention solves at least some of the aforementioned problems associated with conventional devices by providing an organic light emitting display (OLED) and method of fabricating the same, in which an insulating layer is etched using a reflecting layer pattern as an etching mask to form a via contact hole, thereby reducing the number of photolithography and etching steps and reducing the manufacturing costs.

Additional features of the invention will be set forth in the description which follows, and in part will be apparent from the description, or may be learned by practice of the invention.

The present invention also discloses an organic light emitting display (OLED) having a passivation layer including a first via contact hole formed therethrough, wherein the passivation layer is arranged above a substrate on which a thin film transistor having a gate electrode, a source electrode and a drain electrode are formed, wherein the first via contact hole exposes either one of the source electrode or the drain electrode. Also included are a stacked structure comprising a planarization layer pattern and a reflecting layer pattern formed above the passivation layer, wherein the planarization layer pattern and the reflecting layer include a second via contact hole therethrough exposing the first via contact hole, and share an etching surface in a thin film transistor region. The invention further includes a pixel electrode formed on the reflecting layer pattern and contacting either the source electrode or the drain electrode through the second via contact hole, and an insulating layer pattern formed above portions of the passivation layer and the pixel electrode and exposing a pixel region while filling at least a portion of the second via contact hole.

The present invention also discloses an organic light emitting display (OLED) having, a stacked structure including a first insulating layer pattern and a reflecting layer pattern formed above a substrate, a thin film transistor including a gate electrode, a source electrode, and a drain electrode formed on the substrate, wherein the first insulating layer pattern and the reflecting layer pattern comprise a via contact hole therethrough which exposes either the source electrode or the drain electrode and sharing an etching surface in a thin film transistor region. Also included are a pixel electrode formed on the reflecting layer pattern and contacting either the source electrode or the drain electrode through the via contact hole. The invention further discloses a second insulating layer pattern formed above predetermined portions of the thin film transistor and the pixel electrode and exposing a portion of the pixel electrode to define a pixel region and filling at least a portion of the via contact hole.

The invention also discloses a method for fabricating an organic light emitting display (OLED) including forming a buffer layer having a predetermined thickness on a substrate, and forming a thin film transistor including a gate electrode, a source electrode and a drain electrode. The invention further discloses forming a passivation layer above the buffer layer, and etching the passivation layer to form a first via contact hole which exposes either the source electrode or the drain electrode. Also disclosed are forming a planarization layer on predetermined portions of the passivation layer and forming a reflecting layer on predetermined portions of the planarization layer, and etching the reflecting layer to form a reflecting layer pattern. The invention additionally discloses etching the planarization layer using the reflecting layer pattern as an etching mask to form a second via contact hole which exposes the first via contact hole, and forming a pixel electrode contacting either the source electrode or the drain electrode through the first via contact hole and the second via contact hole. The invention further discloses forming an insulating layer pattern on a predetermined portion of the pixel electrode to define a pixel region on the OLED.

The invention also discloses a method of fabricating an organic light emitting display (OLED) including forming a buffer layer having a predetermined thickness on a substrate, and forming a thin film transistor including a gate electrode, a source electrode and a drain electrode on the buffer layer, and forming a first insulating layer over the buffer layer and forming a reflecting layer over the first insulating layer. The invention additionally discloses etching the reflecting layer to form a reflecting layer pattern, and etching the first insulating layer using the reflecting layer pattern as an etching mask to form a via contact hole therethrough which exposes either the source electrode or the drain electrode. The invention further discloses forming a pixel electrode coupled to either one of the source electrode or the drain electrode through the via contact hole, and forming a second insulating layer pattern to define a pixel region on the OLED.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1A, FIG. 1B and FIG. 1C are cross-sectional views illustrating a method of fabricating a conventional OLED.

FIG. 2A, FIG. 2B and FIG. 2C are cross-sectional views illustrating a method of fabricating an OLED according to an embodiment of the present invention.

FIG. 3 is a cross-sectional view of an OLED fabricated according to another embodiment of the present invention.

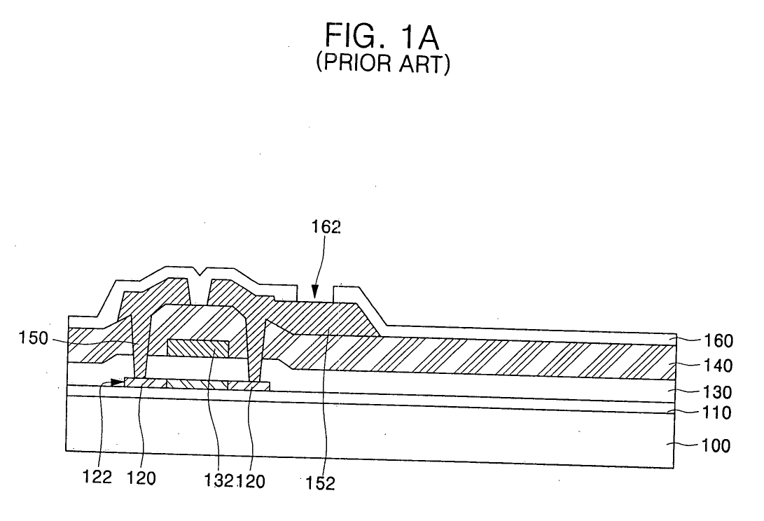

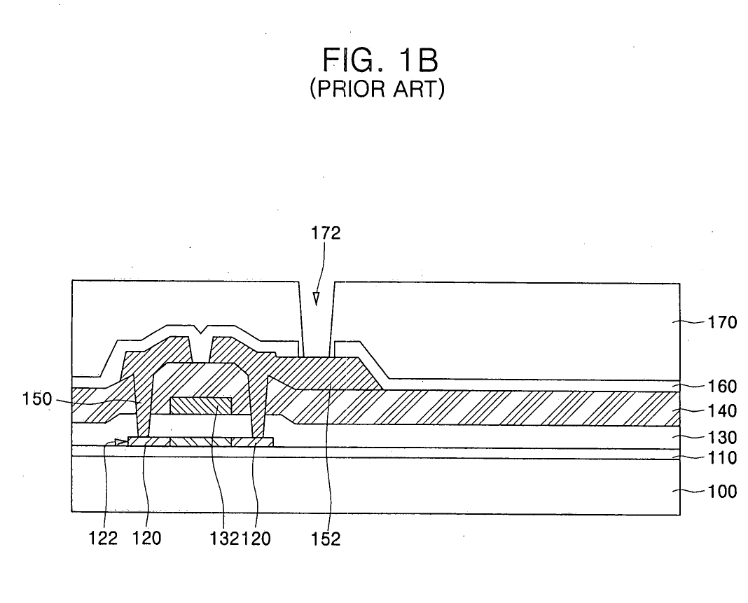

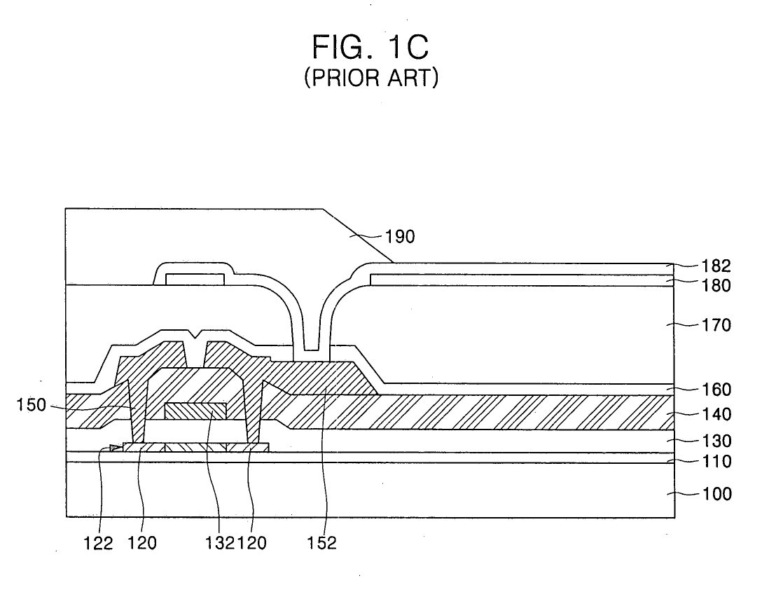

### DETAILED DESCRIPTION OF THE ILLUSTRATED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

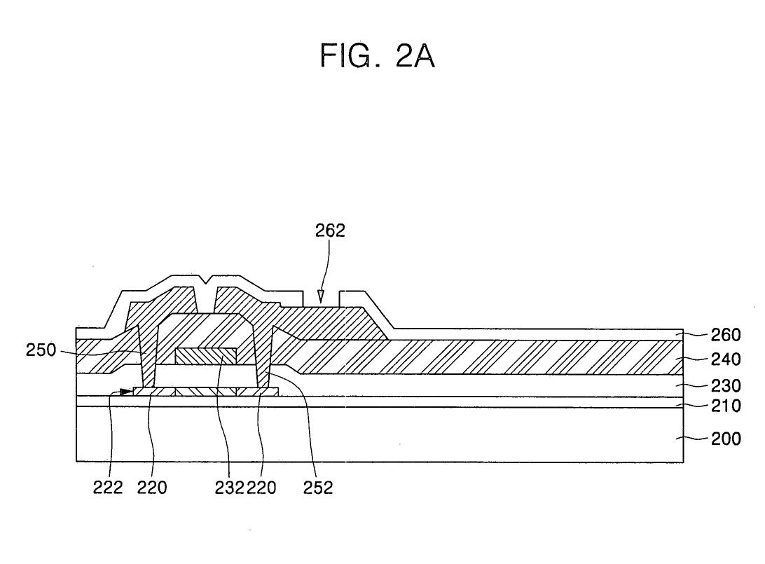

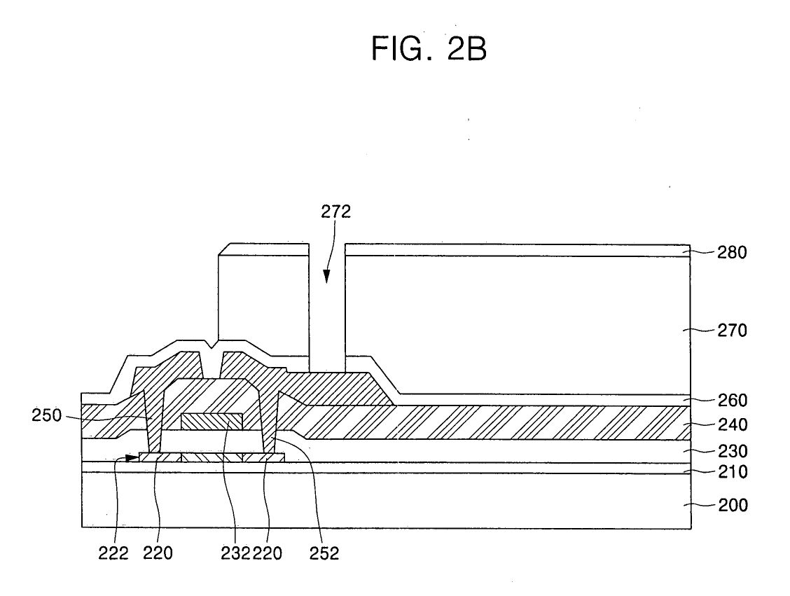

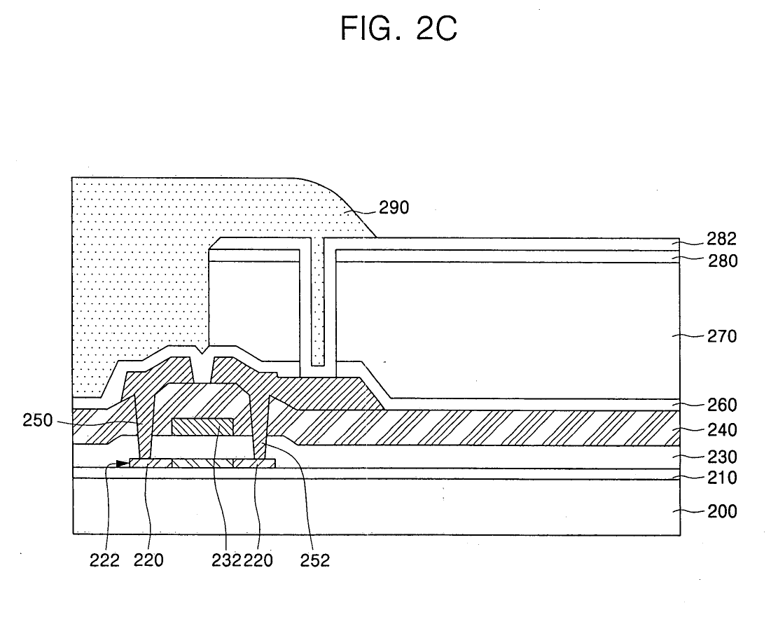

Referring to FIG. 2A, a buffer layer 210 having a predetermined thickness may be formed on a substrate 200 using, for example, a plasma-enhanced chemical vapor deposition (PECVD) method. The substrate 200 may be made of any suitable transparent dielectric, such as, for example, glass, quartz, sapphire, etc., and the buffer layer 210 may be made of silicon oxide. The buffer layer 210 serves to reduce or prevent impurities which may be in the substrate 200 from diffusing into upper layers during a subsequent crystallization process of an amorphous silicon layer which will be formed in later steps.

An amorphous silicon layer having a predetermined thickness is deposited on the buffer layer 210 and is then crystallized. The amorphous silicon layer may be crystallized by any appropriate method, for example, an excimer laser annealing (ELA) method, a sequential lateral solidification (SLS) method, a metal induced crystallization (MIC) method, or a metal induced lateral crystallization (MILC) method. The crystallized amorphous silicon layer is then patterned by photolithography and a suitable etching process to form a polysilicon pattern 222 for a thin film transistor (TFT) region for a unit pixel. The polysilicon pattern 222 includes space for source and drain regions 220 which will be formed in subsequent processes.

After the polysilicon pattern 222 is formed, a gate insulating layer 230 having a predetermined thickness is formed over the polysilicon pattern 222 and buffer layer 210. The gate insulating layer 230 may be made of any suitable dielectric, such as, for example, silicon oxide or silicon nitride.

A metal layer (not shown) is then formed on the gate insulating layer 230 as a gate electrode material layer. The metal layer may be formed of a single layer of aluminum (Al), an aluminum alloy such as aluminum-neodymium (AlNd), or as multiple layers in which an aluminum alloy is formed on another metal such as, for example, chromium (Cr) or molybdenum (Mo). Subsequently, the metal layer is etched by photolithography and suitable etching process to form a gate electrode 232. Impurity ions are then implanted into both sides of the polysilicon pattern 222 which are not covered by the gate electrode 232, i.e. the gate electrode 232 is used as a mask during ion implantation to form source and drain regions 220.

An interlayer insulating layer 240 having a predetermined thickness may then be formed over the gate electrode 232 and gate insulating layer 230. The interlayer insulating layer 240 may be made of any suitable dielectric, and is preferably made of silicon nitride.

The interlayer insulating layer 240 and the gate insulating layer 230 are etched by photolithography and an appropriate etching process to form contact holes which expose the source and drain regions 220. After the contact holes are formed, an electrode material layer is formed over the interlayer insulating layer 240 and within the contact holes. The electrode material layer may be made of molybdenum-tungsten (MoW) or aluminum-neodymium (AlNd). The electrode material layer is then etched by photolithography and a suitable etching process to form a source electrode 250 and a drain electrode 252 which are coupled to the source and drain regions 220.

After electrode formation, a silicon nitride layer may be deposited to a predetermined thickness over the interlayer insulating layer 240, source electrode 250, and drain electrode 252 to form a passivation layer 260. The passivation layer 260 is then etched by photolithography and an appropriate etching process to form a first via contact hole 262 which exposes the drain electrode 252. Alternatively, the source electrode 250 may be exposed by a via contact hole.

Referring to FIG. 2B, a planarization layer 270 is formed over portions of the passivation layer 260. The planarization layer 270 may be made of a material selected from a group of materials including polyimide, benzocyclobutene-based resin, spin on glass (SOG), and acrylate. A reflecting layer may then be formed on the planarization layer 270 using a metal, such as, for example, aluminum (Al), silver (Ag) or an alloy thereof. The reflecting layer should be made of a metal having a high reflectivity which serves to reflect external light to improve the performance of the pixel. The reflecting layer may be etched by photolithography and a suitable etching process to form a reflecting layer pattern 280 over the planarization layer 270. It should be noted that the etching mask used in the photolithography and etching process of the reflecting layer may be thicker than a conventional etching mask and may have different thickness depending on material of the planarization layer 270. Also, the reflecting layer may be etched by a wet-etching method or a dry-etching method to form the reflecting layer pattern 280. Additionally, the reflecting layer pattern 280 may be formed to have a minimum size in any region except for the emission region of the pixel.

The planarization layer 270 may be etched using the reflecting layer pattern 280 as an etching mask to form a second via contact hole 272. The second via contact hole 272 exposes a portion of the drain electrode 252 through the first via contact hole 262. In an alternate embodiment, a second via contact hole may expose a portion of the source electrode 250. Due to the etching process, the reflecting layer pattern 280 and the planarization layer 270 are formed to have a stacked or layered structure having the same etching surface in the TFT region. The stacked structure should preferably have a sufficient width so that it is not etched away during the etching process. The planarization layer 270 may be etched by, for example, a dry-etching method using oxygen (O₂) plasma. When the planarization layer 270 contains silicon such as when it is formed from a SOG layer or a benzocyclobutene-based resin layer, it may be etched by a dry-etching method using plasma with CF₄ or SF₆ gas containing oxygen and fluorine.

Referring to FIG. 2C, a thin layer for a pixel electrode may then be formed over the surface of the reflecting layer pattern 280 and along the walls of the second via contact hole 272. Additionally, the exposed surface of the drain electrode 252 at the bottom of the second contact hole 272 is also covered by the pixel electrode thin layer. The pixel electrode thin layer is made of a transparent conductive material such as, for example, indium tin oxide (ITO). The pixel electrode thin layer is then patterned by photolithography and a suitable etching process to form a pixel electrode 282.

An insulating layer may then be formed over a portion of the surface of the structure including the pixel electrode 282 and the passivation layer 260 to define a pixel region over the pixel electrode 282. The insulating layer may be made of a material selected from a group of materials including polyimide, a benzocyclobutene-based resin, a phenol-based resin, and acrylate. The insulating layer may be etched by photolithography and an appropriate etching process to form an insulating layer pattern 290 which defines a pixel region over the pixel electrode 282.

As an alternate embodiment of the present invention, in order to form a via contact hole through the planarization layer 270 and passivation layer 260 after the reflecting layer pattern 280 has been formed, the planarization layer 270 and the passivation layer 260 may be simultaneously etched using the reflecting layer pattern 280 as an etching mask. In this case, the process of forming the first via contact hole 262 may be omitted because the planarization layer 270 and the passivation layer 260 are etched together to form a contact via hole therethrough.

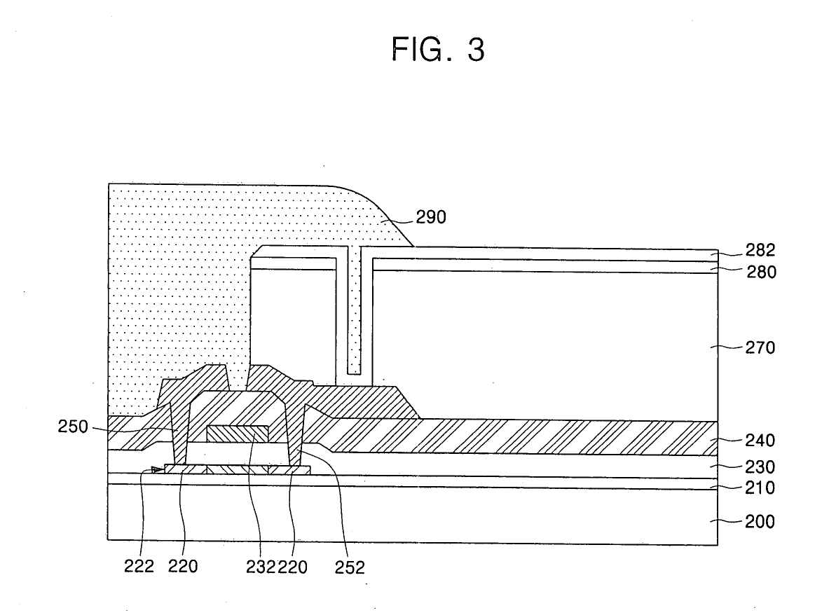

Referring to FIG. 3, a cross-sectional view of an OLED is shown which may be fabricated according to another embodiment of the present invention. The embodiment of FIG. 3 is similar to the completed embodiment shown in FIG. 2C except there is no passivation layer (shown as passivation layer 260 in FIG. 2C) formed between the interlayer insulating layer 240 and the planarization layer 270. In other words, the planarization layer 270 and the reflecting layer pattern 280 are formed by substantially the same process as described above for forming the respective layers with no passivation layer between the interlayer insulating layer 240 and the planarization layer 270. Thus, the processes of forming the passivation layer 260 of FIG. 2C and a first via contact hole 262 of FIG. 2A may be omitted in some embodiments.

As described above, according to embodiments of the present invention, the planarization layer is etched using the reflecting layer pattern as an etching mask without using photolithography and etching processes to form a via contact hole through layers located between the drain electrode and the planarization layer. Consequently, at least one or two photolithography and etching processes may be eliminated, which accordingly reduces the costs and potential for frequently caused fabrication errors which would otherwise result from the eliminated etching process. Accordingly, manufacturing yield is improved and manufacturing costs are lowered.

It will be apparent to those skilled in the art that various modifications and variations can be made in the present invention without departing from the spirit or usage of the invention. Thus, it is intended that the present invention cover the modifications and variations of this invention provided they come within the scope of the appended claims and other equivalents.

1. An organic light emitting display (OLED), comprising:
a passivation layer including a first via contact hole formed therethrough, wherein the passivation layer is arranged above a substrate on which a thin film transistor having a gate electrode, a source electrode and a drain electrode are formed, wherein the first via contact hole exposes either one of the source electrode or the drain electrode;
a stacked structure comprising a planarization layer pattern and a reflecting layer pattern formed above the passivation layer, wherein the planarization layer pattern and the reflecting layer include a second via contact hole therethrough exposing the first via contact hole, and share an etching surface in a thin film transistor region;
a pixel electrode formed on the reflecting layer pattern and contacting either the source electrode or the drain electrode through the second via contact hole; and
an insulating layer pattern formed above portions of the passivation layer and the pixel electrode and exposing a pixel region while filling at least a portion of the second via contact hole.

2. The OLED of claim 1, wherein the planarization layer pattern is made of a material selected from a group of materials consisting of polyimide, benzocyclobutene-based resin, spin on glass (SOG), and acrylate.

3. The OLED of claim 1, wherein the reflecting layer pattern comprises a metal selected from a group of metals consisting of aluminum, silver, or an alloy of silver and aluminum.

4. An organic light emitting display (OLED), comprising:
a stacked structure including a first insulating layer pattern and a reflecting layer pattern formed above a substrate, a thin film transistor including a gate electrode, a source electrode, and a drain electrode formed on the substrate, wherein the first insulating layer pattern and the reflecting layer pattern comprise a via contact hole therethrough which exposes either the source electrode or the drain electrode and share an etching surface in a thin film transistor region;
a pixel electrode formed on the reflecting layer pattern and contacting either the source electrode or the drain electrode through the via contact hole; and
a second insulating layer pattern formed above predetermined portions of the thin film transistor and the pixel electrode and exposing a portion of the pixel electrode to define a pixel region and filling at least a portion of the via contact hole.

5. The OLED of claim 4, wherein the first insulating layer pattern comprises a material selected from a group of materials consisting of polyimide, benzocyclobutene-based resin, spin on glass (SOG), and acrylate.

6. The OLED of claim 4, wherein the first insulating layer pattern comprises a stacked structure including a planarization layer and a passivation layer.

7. The OLED of claim 6, wherein the passivation layer comprises any one of a silicon nitride layer, a silicon oxide layer, and a stack of a silicon nitride layer and a silicon oxide layer.

8. The OLED of claim 4, wherein the reflecting layer pattern comprises a metal selected from a group of metals consisting of aluminum, silver, or an alloy of silver and aluminum.

9. A method of fabricating an organic light emitting display (OLED), comprising:
forming a buffer layer having a predetermined thickness on a substrate, and forming a thin film transistor including a gate electrode, a source electrode and a drain electrode;
forming a passivation layer above the buffer layer;
etching the passivation layer to form a first via contact hole which exposes either the source electrode or the drain electrode;
forming a planarization layer on predetermined portions of the passivation layer and forming a reflecting layer on predetermined portions of the planarization layer;
etching the reflecting layer to form a reflecting layer pattern;
etching the planarization layer using the reflecting layer pattern as an etching mask to form a second via contact hole which exposes the first via contact hole;
forming a pixel electrode contacting either the source electrode or the drain electrode through the first via contact hole and the second via contact hole; and
forming an insulating layer pattern on a predetermined portion of the pixel electrode to define a pixel region on the OLED.

10. The method of claim 9, wherein the planarization layer comprises a material selected from a group of materials consisting of polyimide, benzocyclobutene-based resin, spin on glass (SOG), and acrylate.

11. The method of claim 9, wherein the reflecting layer pattern comprises a metal selected from a group of metals consisting of aluminum, silver, or an alloy of silver and aluminum.

12. The method of claim 9, wherein the reflecting layer is etched by either a wet-etching method or a dry-etching method.

13. The method of claim 9, wherein the planarization layer is etched by a dry-etching method using oxygen plasma.

14. The method of claim 9, wherein the planarization layer is etched by a dry-etching method using a plasma with either one of a CF₄ or a SF₆ gas and comprising at least oxygen and fluorine when the planarization layer comprises silicon.

15. A method of fabricating an organic light emitting display (OLED), comprising:
forming a buffer layer including a predetermined thickness on a substrate, and forming a thin film transistor including a gate electrode, a source electrode and a drain electrode on the buffer layer;
forming a first insulating layer over the buffer layer and forming a reflecting layer over the first insulating layer;
etching the reflecting layer to form a reflecting layer pattern;
etching the first insulating layer using the reflecting layer pattern as an etching mask to form a via contact hole therethrough which exposes either one of the source electrode or the drain electrode;
forming a pixel electrode coupled to either one of the source electrode or the drain electrode through the via contact hole; and
forming a second insulating layer pattern to define a pixel region on the OLED.

16. The method of claim 15, wherein the first insulating layer is made of a material selected from a group of materials consisting of polyimide, benzocyclobutene-based resin, spin on glass (SOG), and acrylate.

17. The method of claim 15, wherein the first insulating layer comprises a passivation layer under a planarization layer.

18. The method of claim 17, wherein the passivation layer is formed of one of either a silicon nitride layer, a silicon oxide layer, or a stack of a silicon nitride layer and a silicon oxide layer.

19. The method of claim 15, wherein the reflecting layer pattern comprises a metal selected from a group of metals consisting of aluminum, silver, or an alloy of aluminum and silver.

20. The method of claim 15, wherein the reflecting layer is etched by either a wet-etching method or a dry-etching method.

21. The method of claim 15, wherein the planarization layer is etched by a dry-etching method using oxygen plasma.

22. The method of claim 15, wherein the planarization layer is etched by a dry-etching method using a plasma with either one of a CF₄ or SF₆ gas containing at least oxygen and fluorine when the planarization layer contains silicon.
